(19) United States
(12) Patent Application Publication
(10) Pub. No.: US 2026/0173928 A1
(43) Pub. Date: Jun. 18, 2026

(54) PLATED METAL ON PAD AND TRACE FOR METAL CONSUMPTION AND PDN PERFORMANCE IMPROVEMENT

(71) Applicant: QUALCOMM Incorporated, San Diego, CA (US)

(72) Inventors: Joan Rey Villarba BUOT, Escondido, CA (US); Aniket PATIL, San Diego, CA (US); Yu-Ting HUANG, Taoyuan Dist (TW)

(21) Appl. No.: 19/407,878

(22) Filed: Dec. 3, 2025

Related U.S. Application Data
(60) Provisional application No. 63/733,203, filed on Dec. 12, 2024.

(51) Int. Cl. H10W 70/65; H10W 70/05; H10W 70/63

(52) U.S. Cl. CPC H10W 70/65; H10W 70/095; H10W 70/635

(57) ABSTRACT

Disclosed are semiconductor packages. The mobile roadmap requires fine line/space (L/S) dimensions such as 5/7, 5/5 or even finer. This requires very thin metal (e.g., copper) thickness to keep substrate manufacturing yield. Unfortunately, metal such as copper can be consumed which reduces reliability. To address such issues, a semiconductor package may include a plated metal, such as copper, underneath connection pads such as IOP pads, peripheral pads, core bumps, etc. The additional metal can compensate and add buffer for metal consumption. It can also improve PDN performance.

### CROSS-REFERENCE TO RELATED APPLICATION

The present Application for Patent claims the benefit of U.S. Provisional Ser. No. 63/733,203 entitled “PLATED METAL ON PAD AND TRACE FOR METAL CONSUMPTION AND PDN PERFORMANCE IMPROVEMENT,” filed Dec. 12, 2024, assigned to the assignee hereof, and expressly incorporated herein by reference in its entirety.

### BACKGROUND OF THE DISCLOSURE

### 1. Field of the Disclosure

This disclosure relates generally to die packages or modules, and more specifically, but not exclusively, to plated metal on pad and trace for metal consumption and power distribution network (PDN) performance improvement and fabrication techniques thereof.

### 2. Description of the Related Art

Integrated circuit (IC) technology has achieved great strides in advancing computing power through miniaturization of active components. Premium tier mobile roadmap indicates that fine line/space (L/S) should be reduced from current 6 μm/8 μm (6/8) to 5/7, 5/5 or even smaller for pitch reduction to stay competitive in terms of package form factor. Fine 5/7 or 5/5 or lower means that the copper (Cu) thickness may be reduced to keep substrate manufacturing yield to acceptable levels. However, Cu may be consumed. For example, after being subjected to high temperature storage (HTS) for 1000 hours, 7 μm may be consumed. If the initial thickness Cu is reduced, e.g., to 10 μm to achieve the fine L/S pitches, then the consumption of the Cu can reduce reliability of the semiconductor package. Accordingly, there is a need for systems, apparatus, and methods that overcome the deficiencies of conventional semiconductor packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly,

the following summary has the sole purpose to present certain concepts relating to one or more aspects and/or examples relating to the apparatus and methods disclosed herein in a simplified form to precede the detailed description presented below.

An exemplary semiconductor package is disclosed. The semiconductor package may comprise a substrate with a first surface facing upward and a second surface facing downward. The semiconductor package may also comprise one or more vias within the substrate and extending from the first and second surfaces of the substrate. Upper surfaces of the one or more vias may be planar with the first surface of the substrate and lower surfaces of the one or more vias may be planar with the second surface of the substrate. The semiconductor package may further comprise a first metal layer on the first surface of the substrate. The first metal layer may comprise one or more first connection pads, one or more first traces, and one or more first via pads. The upper surfaces of the one or more vias may be electrically coupled with the one or more first via pads. The semiconductor package may yet comprise a second metal layer on the second surface of the substrate. The second metal layer may comprise one or more second connection pads, one or more second traces, and one or more second via pads. The lower surfaces of the one or more vias may be electrically coupled with the one or more second via pads. The semiconductor package may yet further comprise one or more plated metals within the substrate below the first surface of the substrate. An upper surface of at least one plated metal may be in contact with a lower surface of at least one first connection pad or a lower surface of at least one first trace.

A method of fabricating a semiconductor package is disclosed. The method may comprise providing a substrate with a first surface facing upward and a second surface facing downward. The method may also comprise forming one or more vias within the substrate and extending from the first and second surfaces of the substrate. Upper surfaces of the one or more vias may be planar with the first surface of the substrate and lower surfaces of the one or more vias may be planar with the second surface of the substrate. The method may further comprise forming a first metal layer on the first surface of the substrate. The first metal layer may comprise one or more first connection pads, one or more first traces, and one or more first via pads. The upper surfaces of the one or more vias may be electrically coupled with the one or more first via pads. The method may yet comprise forming a second metal layer on the second surface of the substrate. The second metal layer may comprise one or more second connection pads, one or more second traces, and one or more second via pads. The lower surfaces of the one or more vias may be electrically coupled with the one or more second via pads. The method may yet further comprise forming one or more plated metals within the substrate below the first surface of the substrate. An upper surface of at least one plated metal may be in contact with a lower surface of at least one first connection pad or a lower surface of at least one first trace.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a cross-sectional view of a conventional semiconductor package.

FIG. 2 illustrates a cross-sectional view of a semiconductor package in accordance with one or more aspects of the disclosure.

FIGS. 3A-3J illustrate examples of stages of fabricating a semiconductor package in accordance with one or more aspects of the disclosure.

FIGS. 4A, 4B and 5 illustrate flow charts of example methods of manufacturing a semiconductor package in accordance with at one or more aspects of the disclosure.

FIG. 6 illustrates various electronic devices which may utilize one or more aspects of the disclosure.

FIG. 7 lists some of the issues with conventional semiconductor packages and some proposals to address those issues.

FIG. 8 visually illustrates direct current resistances (DCR) of the conventional and proposed semiconductor packages.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor packages and methods for fabricating the same. In an aspect, the semiconductor package may comprise a substrate with a first surface facing upward and a second surface facing downward. The semiconductor package may also comprise one or more vias within the substrate and extending from the first and second surfaces of the substrate. Upper surfaces of the one or more vias may be planar with the first surface of the substrate and lower surfaces of the one or more vias may be planar with the second surface of the substrate. The semiconductor package may further comprise a first metal layer on the first surface of the substrate. The first metal layer may comprise one or more first connection pads, one or more first traces, and one or more first via pads The upper surfaces of the one or more vias may be electrically coupled with the one or more first via pads. The semiconductor package may yet comprise a second metal layer on the second surface of the substrate. The second metal layer may comprise one or more second connection pads, one or more second traces, and one or more second via pads. The lower surfaces of the one or more vias may be electrically coupled with the one or more second via pads. The semiconductor package may yet further comprise one or more plated metals within the substrate below the first surface of the substrate. An upper surface of at least one plated metal may be in contact with a lower surface of at least one first connection pad or a lower surface of at least one first trace. In this way, consumption of plated metal may be reduced.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

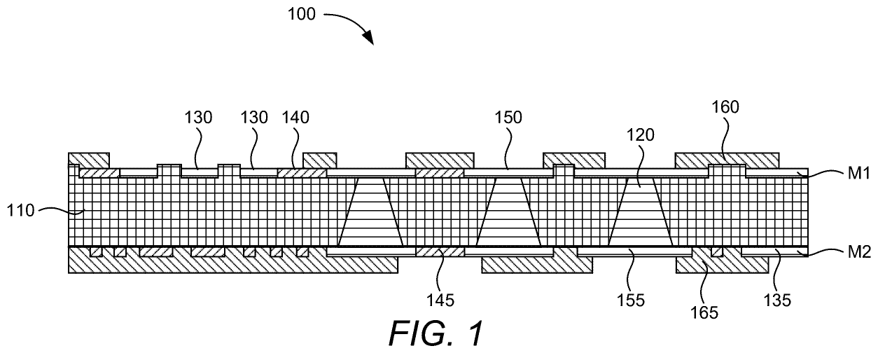

FIG. 1 illustrates a cross-sectional view of a conventional semiconductor package 100. The conventional semiconductor package 100 includes a dielectric 110 with an upward facing surface, referred to as first surface, and a downward facing surface, referred to as a second surface. There are also vias 120, formed from copper, within the dielectric 110. The vias extend from the first and second surfaces of the dielectric 110.

A first metal layer M1 is on the first surface of the dielectric 110. The first metal layer M1 comprises first IOP pads 130, first traces 140, and first via pads 150. Upper surfaces of the vias 120 are in contact with the first via pads 150. Similarly, second metal layer M2 is on the second surface of the dielectric 110. The second metal layer M2 comprises second IOP pads 135, second traces 145, and second via pads 155. Lower surfaces of the one or more vias 120 are in contact with the second via pads 155. First solder resists (SR) 160 are formed on and above the dielectric 110 and on the first metal layer M1. Second SR 165 are formed on and below the dielectric 110 and on the second metal layer M2.

As indicated above, premium tier mobile roadmap indicates that fine line/space (L/S) should be reduced from current 6/8 to 5/7, 5/5 or even smaller for pitch reduction to stay competitive in terms of package form factor. Conventionally, the thickness of the first metal layer M1, and hence the thickness of the first IOP pads 130, first traces 140, and first via pads 150, is 14 μm (or greater), which is sufficient to achieve the 6/8 L/S.

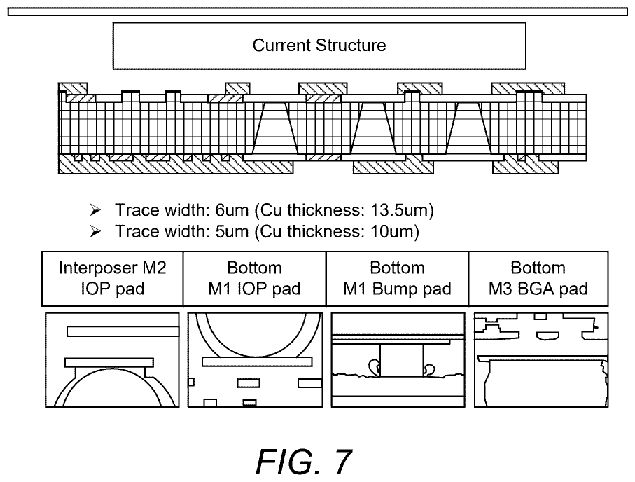

Recall that Cu consumption may be as high as 7 μm or more when subjected to HTS of 1000 hours. This is visually illustrated in FIG. 7. For example, an example of a bottom M1 IOP pad is shown. The pad is below a ball with solder resist in between contacting both the pad and the ball. Note that the Cu on the pad is consumed. This is shown by the solder resist penetrating the pad from above. But with the initial Cu thickness of 14 μm or greater, enough Cu remains after the consumption (e.g., under HTS 1000 hrs) so that the reliability may be maintained within acceptable levels.

However to achieve the fine L/S of 5/7 or 5/5 or even less, this means the initial Cu thickness should be reduced to 10 μm or less. This means that with high Cu consumption of 7 μm or more, the reliability of the semiconductor package can be significantly reduced. There can be other technical disadvantages. For example, for hard macro bumps placed in periphery bumps region, neural central processing (NCP) bleed out can occur due to open trench. This can prohibit the peripheral bumps from merging with shape. Also, connectivity from the concerned bump is normally performed using traces. The trace is resistive than and simulation indicates that the bump-to-ball has upto two time the DCR compared to neighboring power bumps of APC rail in vicinity.

To address these and other issues of the conventional semiconductor package, it is proposed to provide additional plated Cu or plated NiAu, or more generally, additional plated metal on the pads (e.g., peripheral pads, core bump pads, IOP pads, etc.). This can increase thickness for metal trace running from bump to via pads. The increase in thickness on peripheral bump pads can mitigate the metal (e.g., Cu) consumption for reliability purposes. That is, the additional metal thickness can compensate and buffer for metal consumption.

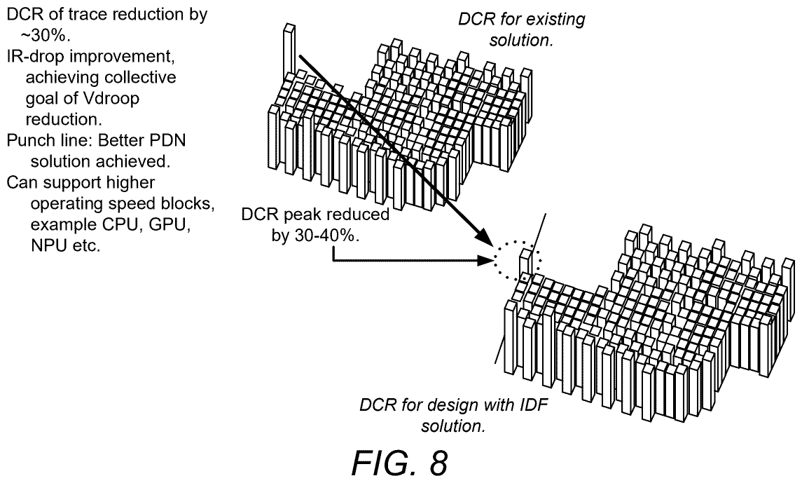

Selective metal thickness increase can further address power distribution network (PDN) concerned regions. That is, the PDN to L/S devices can be improved. Further, the increase in the metal thickness can contribute to more metal volume for local region, which eases current path and reduce sheet resistance. For example, as shown in FIG. 8, the direct current resistance (DCR) of traces can be reduced by 30% or more. This means that higher operating speeds can be achieved for CPU, GPU, NPU (neural processing unit), etc.

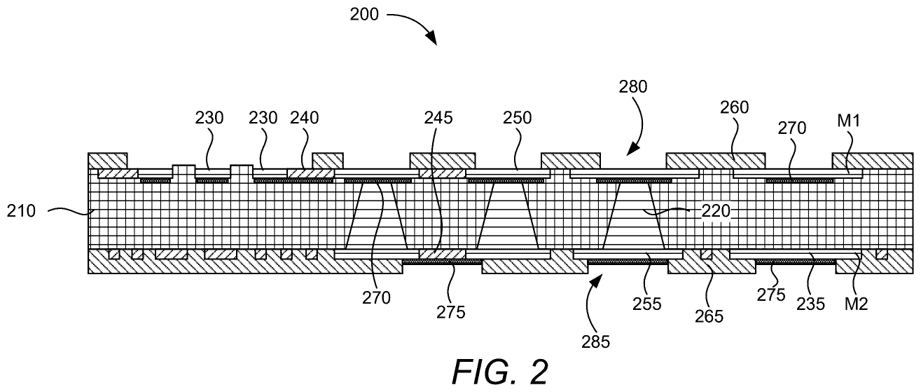

FIG. 2 illustrates a cross-sectional view of a semiconductor package 200 in accordance with one or more aspects of the disclosure. The semiconductor package 200 may include a substrate 210 and one or more vias 220 within the substrate 210. The substrate 210 may be a dielectric, a laminate, a prepreg (PPG), a coreless substrate, an embedded trace substrate (ETS), or any combination thereof. The substrate 210 may have a first surface facing upward and a second surface facing downward. Before proceeding further, it should be understood that terms or phrases such as “upward”, “downward”, “left”, “right”, etc. are used for convenience. Unless stated explicitly stated otherwise, such terms should NOT be taken to mean absolute directions.

The one or more vias 220 may be within the substrate 210 and extend from the first and second surfaces of the substrate 210. The one or more vias 220 may be formed from conductive metals such as copper (Cu). Upper surfaces of the one or more vias 220 may be planar with the first surface of the substrate 210. Alternatively or in addition thereto, there may be one or more plated metals 270 (described further below) on upper surfaces of some or all of the one or more vias 220. In this instance, upper surfaces of the plated metals 270 may be planar with the first surface of the substrate 210. Lower surfaces of the one or more vias 220 may be planar with the second surface of the substrate 210. Alternatively or in addition thereto, there may be one or more second plate metals 275 (also described further below) on lower surfaces of some or all of the one or more vias 220. In this instance, lower surfaces of the second plate metals 275 may be planar to the second surface of the substrate 210.

A first metal layer M1 may be on the first surface of the substrate 210. For example, the first metal layer M1 may be in contact with the first surface of the substrate 210. The first metal layer M1 may comprise one or more first connection pads 230, one or more first traces 240, and/or one or more first via pads 250. The first metal layer M1 may be formed from conductive metals such as Cu. That is, the one or more first connection pads 230, the one or more first traces 240, and/or the one or more first via pads 250 may be formed from conductive metals, e.g., Cu. The upper surfaces of the one or more vias 220 may be electrically coupled with the one or more first via pads 250. For example, they may be in contact with each other. Alternatively, there may be plated metals 270 between the one or more vias 220 and the one or more first via pads 250.

The one or more first connection pads 230 may include one or more IOP pads, or one or more peripheral bump pads, or both. Also, at least one first trace 240 may be a trace from a peripheral bump pad. The thickness of the first metal layer M1 (e.g., thicknesses of the first connection pads 230, the first traces 240, the first via pads 250) may be 10 μm or less so that L/S pitches may be fine. That is, the widths of the one or more first traces 240 may be 5 μm or less, and the spacing between adjacent first traces 240 may be 7 μm or less, or even as small as 5 μm or less. One or more first SRs 260 may be formed on the substrate 210 and on the first metal layer M1 from above.

A second metal layer M2 may be on the second surface of the substrate 210. The second metal layer M2 may comprise one or more second connection pads 235, one or more second traces 245, and/or one or more second via pads 255. The second metal layer M1 may be formed from conductive metals such as Cu. That is, the one or more second connection pads 235, the one or more second traces 245, and/or the one or more second via pads 255 may be formed from conductive metals, e.g., Cu. The lower surfaces of the one or more vias 220 may be electrically coupled with the one or more second via pads 255. For example, they may be in contact with each other.

The one or more second connection pads 235 may include one or more IOP pads, or one or more peripheral bump pads, or both. Also, at least one second trace 245 may be a trace from a peripheral bump pad. The thickness of the second metal layer M2 (e.g., thicknesses of the second connection pads 235, the second traces 245, the second via pads 255) may be 10 μm or less so that L/S pitches may be fine. That is, the widths of the one or more second traces 245 may be 5 μm or less, and the spacing between adjacent second traces 245 may be 7 μm or less, or even as small as 5 μm or less. One or more second SRs 265 may be formed on the substrate 210 and on the second metal layer M2 from below.

To enable protection from consumption of Cu, or more generally protection from consumption of metals, the semiconductor package 200 may also include one or more plated metals 270 within the substrate 210. The one or more plated metals 270 may be below the first surface of the substrate 210. A thickness of the one or more plated metals may be 10 μm or less and may be formed from metals such as Cu and/or NiAu.

In an embodiment, an upper surface of at least one plated metal 270 may be in contact with a lower surface of at least one first connection pad 230 or at least one first trace 240 or at least one first via pad 250. Alternatively or in addition thereto, there can be situations in which at least one first connection pad 230 may be electrically coupled to at least one first trace 240. For example, a side surface of the at least one first connection pad 230 may be in contact with a side surface of at least one first trace 240. In this instance, the upper surface of the at least one plated metal 270 may also be in contact with a lower surface of at least one first connection pad 230 and the at least one first trace 240.

Alternatively or addition to the one or more plated metals 270, there may be one or more second plated metals 275 within the substrate 210 and above the second surface of the substrate 210. When the second plated metals 275 are present, the plated metals 270 may also be referred to as the first plated metals 270. Upper surfaces of the second plated metals 275 may be in contact with a lower surface of at least one second connection pad 235 or at least one second trace 245 or at least one second via pad 255. Alternatively or in addition thereto, the upper surface of the second plated metal 275 may also be in contact with a lower surface of at least one second connection pad 235 and at least one second trace 245 whose side surfaces are in contact with each other.

The semiconductor package 200 may include a first solder resist (SR) 260 on the substrate 210 and on the first metal layer M1 from above. There may be one or more openings—i.e., one or more first SR openings 280—within the first SR 260 that expose one or more portions of the first metal layer M1. For at least one first SR opening 280, a plated metal 270 of the one or more plated metals 270 may be in between the substrate 210 and the first metal layer M1 at a location corresponding to the at least one first SR opening 280. In this instance, an upper surface of the plated metal 270 may be in contact with a lower surface of the first metal layer M1. Note that in an aspect, there may be a plated metal 270 for each location corresponding to the one or more first SR openings 280.

The semiconductor package 200 may also include a second SR 265 on the substrate 210 and on the second metal layer M2 from below. There may be one or more openings—i.e., one or more second SR openings 285—within the second SR 265 that expose one or more portions of the second metal layer M2. For at least one second SR opening 285, a second plated metal 275 of the one or more second plated metals 275 may be at a location corresponding to the at least one second SR opening 285. In this instance, an upper surface of the second plated metal 275 may be in contact with lower surface of the second metal layer M2. Note that in an aspect, there may be a second plated metal 275 for each location corresponding to the one or more second SR openings 285.

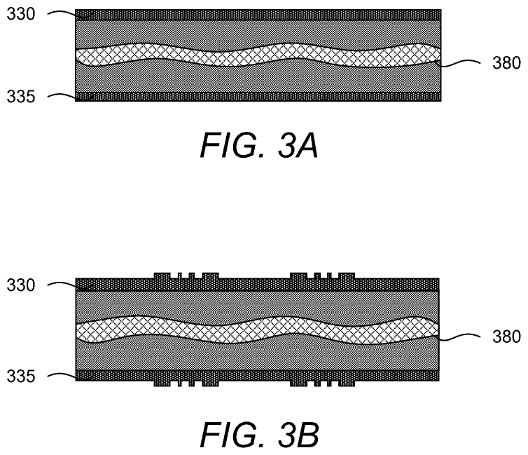

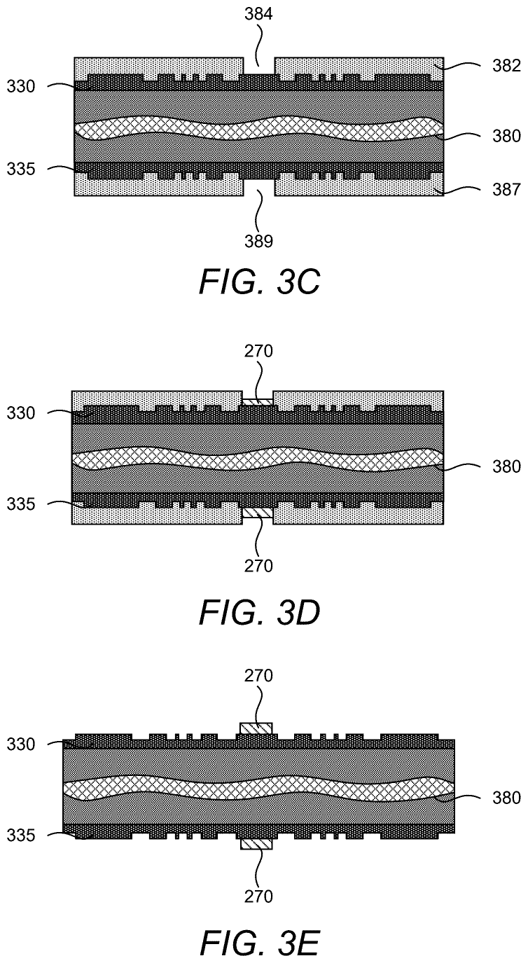

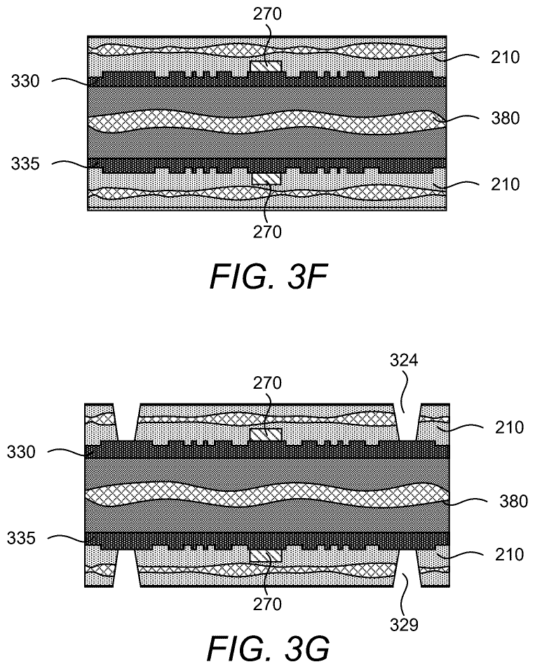

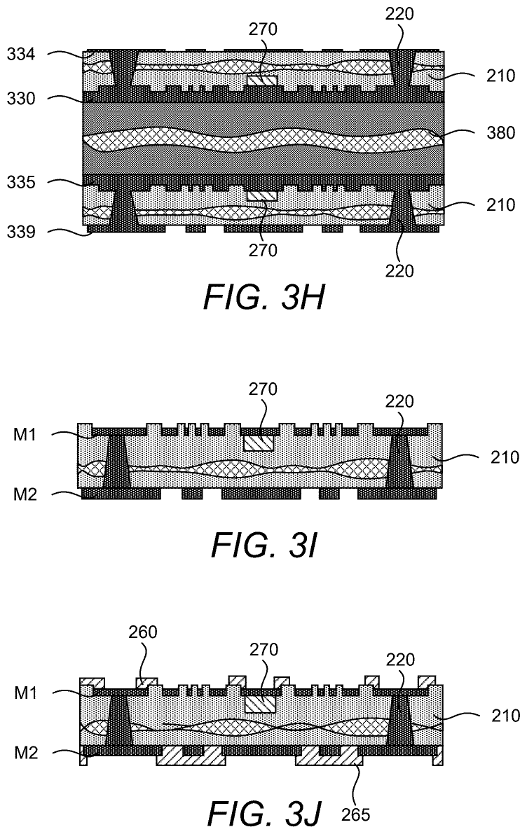

FIGS. 3A-3J illustrate examples of stages of fabricating a semiconductor package, such as the semiconductor package 200, in accordance with one or more aspects of the disclosure. In these figures, forming semiconductor packages on both sides of a carrier is shown. However, this is an example, and should not be taken to be limited only to using a carrier. Also in these figures, the processing of the (first) plated metal 270 are shown. Which not specifically shown, it would be relatively straightforward to adapt the shown fabricating techniques to process the second plated metals 275.

FIG. 3A illustrates a stage in which an upper first metal layer 330 and a lower first metal layer 335 are formed on upper and lower surfaces of a carrier 380.

FIG. 3B illustrates a stage in which the upper and lower first metal layers 330, 335 are patterned. The patterned upper and lower first metal layers 330, 335 may include the first connection pads 230, the first traces 240, and/or the first via pads 250 (not specifically numbered in FIG. 3B).

FIG. 3C illustrates a stage in which an upper mask 382 may be applied on the upper first metal layer 330 and a lower mask 387 may be applied on the lower first metal layer 335. An example of the upper and lower masks may be dry film. One or more upper pattern holes 384 (one shown in the figure) may be formed to expose surfaces of the one or more first connection pads 230 and/or one or more first traces 240 of the upper first metal layer 330. Similarly, one or more lower pattern holes 389 (one shown in the figure) may be formed to expose surfaces of the one or more first connection pads 230 and/or one or more first traces 240 of the lower first metal layer 335.

FIG. 3D illustrates a stage in which a metal (e.g., Cu, NiAu, etc.) may be deposited in the one or more upper and lower pattern holes 384, 389 to form the one or more plated metals 270.

FIG. 3E illustrates a stage in which the upper and lower masks 382, 387 may be removed from the upper and lower first metal layers 330, 335, respectively.

FIG. 3F illustrates a stage in which substrate 210 may be formed on both the patterned upper and lower first metal layers 330, 335. An example of the substrate 210 may be a dielectric, a PPG, a coreless substrate, an ETS, or any combination thereof.

FIG. 3G illustrates a stage in which one or more upper via holes 324 may be formed in the upper substrate 210, and one or more lower via holes 329 may be formed in the lower substrate 210.

FIG. 3H illustrates a stage in which metal (e.g., Cu) may be deposited and patterned to form the vias 220 in the upper and lower via holes 324, 329. The deposited metal may also be patterned to form upper and lower second metal layers 334, 339, which may also be referred to as upper and lower M2 layers. While not specifically numbered, the upper and lower second metal layers 334, 339 may include one or more second connection pads 235, one or more second traces 245, and/or one or more second via pads 255.

FIG. 3I illustrates a stage in which the carrier 380 may be removed. The semiconductor package of FIG. 31 may represent the semiconductor package above the carrier 380 in FIG. 3H or may represent a flipped version of the semiconductor package below the carrier 380 in FIG. 3H.

FIG. 3J illustrates a stage in which the first solder resist (SR) 260 may be formed on the first metal layer M1 and on the substrate 210 from above and the second SR 265 may be formed on the second metal layer M2 and on the substrate 210 from below.

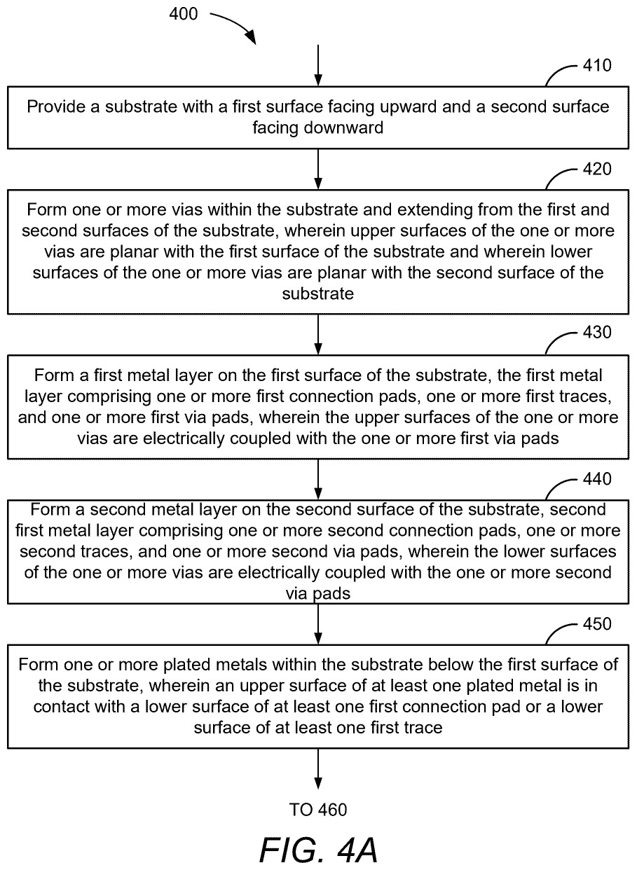

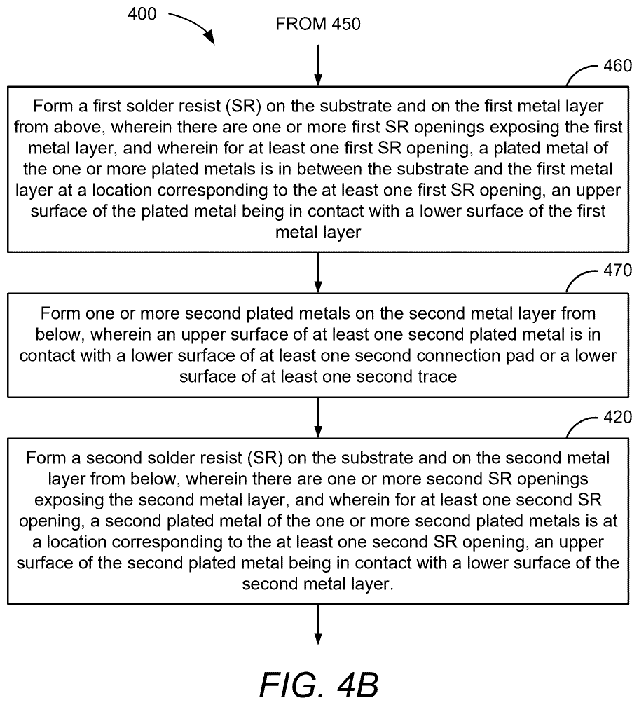

FIGS. 4A and 4B illustrate a flow chart of an example method 400 of fabricating a semiconductor package, such as the semiconductor package 200, in accordance with at one or more aspects of the disclosure.

In block 410, a substrate 210 may be provided. A first surface of the substrate 210 may face upward, and a second surface of the substrate 210 opposite the first surface may face downward.

In block 420, one or more vias 220 may be formed within the substrate 210. The one or more vias 220 may extend from the first and second surfaces of the substrate 210. Upper surfaces of the one or more vias 220 may be planar with the first surface of the substrate 210 and lower surfaces of the one or more vias 220 may be planar with the second surface of the substrate 210.

In block 430, a first metal layer M1 may be formed on the first surface of the substrate 210. The first metal layer M1 may comprise one or more first connection pads 230, one or more first traces 240, and/or one or more first via pads 250. The upper surfaces of the one or more vias 220 may be electrically coupled with the one or more first via pads 250.

In block 440, a second metal layer M2 may be formed on the second surface of the substrate 210. The second metal layer M2 may comprise one or more second connection pads 235, one or more second traces 245, and/or one or more second via pads 255. The lower surfaces of the one or more vias 220 may be electrically coupled with the one or more second via pads 255.

In block 450, one or more plated metals 270 (also may be referred to as first plated metals 270) may be formed within the substrate 210. The one or more plated metals 270 may be below the first surface of the substrate 210. An upper surface of at least one plated metal 270 may be in contact with a lower surface of at least one first connection pad 230 and/or a lower surface of at least one first trace 240.

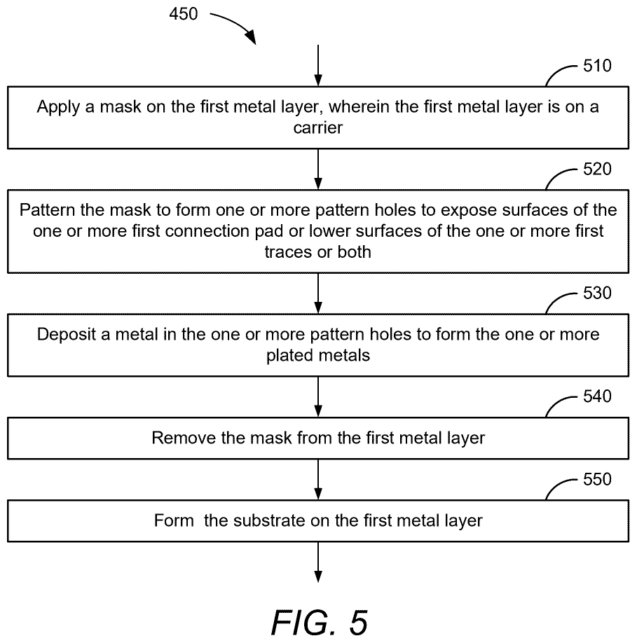

FIG. 5 illustrates a flow chart of an example process to perform block 450 of the method 400. In block 510, a mask (e.g., upper and/or lower masks 382, 387) may be applied on the first metal layer M1 (e.g., on the upper and/or lower first metal layers 330, 335). The first metal layer M1 may be on a carrier (e.g., carrier 380).

In block 520, the mask may be patterned to form one or more pattern holes (e.g., upper and/or lower patterns holes 384, 389) to expose surfaces of the one or more first connection pads 230 or lower surfaces of the one or more first traces 240 or both. Blocks 510 and 520 may correspond to the stage illustrated in FIG. 3C.

In block 530, metal may be deposited in the one or more pattern holes to form the one or more plated metals 270. Block 530 may correspond to the stage illustrated in FIG. 3D.

In block 540, the mask may be removed from the first metal layer M1 (e.g., upper and/or lower first metal layers 330, 335). Block 540 may correspond to the stage illustrated in FIG. 3E.

In block 550, the substrate 210 may be formed on the first metal layer M1 (e.g., upper and/or lower first metal layers 330, 335). Block 540 may correspond to the stage illustrated in FIG. 3F.

Referring back to the flow chart of FIGS. 4A and 4B, in block 460, a first solder resist (SR) 260 may be formed on the substrate 210 and on the first metal layer M1 from above. There may be one or more first SR openings 280 exposing the first metal layer M1. For at least one first SR opening 280, a plated metal 270 of the one or more plated metals 270 may be between the substrate 210 and the first metal layer M1 at a location corresponding to the at least one first SR opening 280. At this location, an upper surface of the plated metal 270 may be in contact with a lower surface of the first metal layer M1.

In block 470, one or more second plated metals 275 may be formed on the second metal layer from below. The one or more second plated metals 275 may be below the second surface of the substrate 210. An upper surface of at least one second plated metal 275 may be in contact with a lower surface of at least one second connection pad 235 or a lower surface of at least one second trace 240.

In block 480, a second SR 265 may be formed on the substrate 210 and on the second metal layer M2 from below. There may be one or more second SR openings 285 exposing the second metal layer M2. For at least one second SR opening 285, a second plated metal 275 of the one or more second plated metals 275 may be at a location corresponding to the at least one second SR opening 285. At this location, an upper surface of the second plated metal 275 being in contact with a lower surface of the second metal layer M2.

The following should be noted regarding the flow indicated in FIGS. 4A, 4B and 5. Unless otherwise indicated, the flow of blocks do not necessarily limit the ordering in which the blocks may be performed. In other words, the blocks may be performed in any order that is logical.

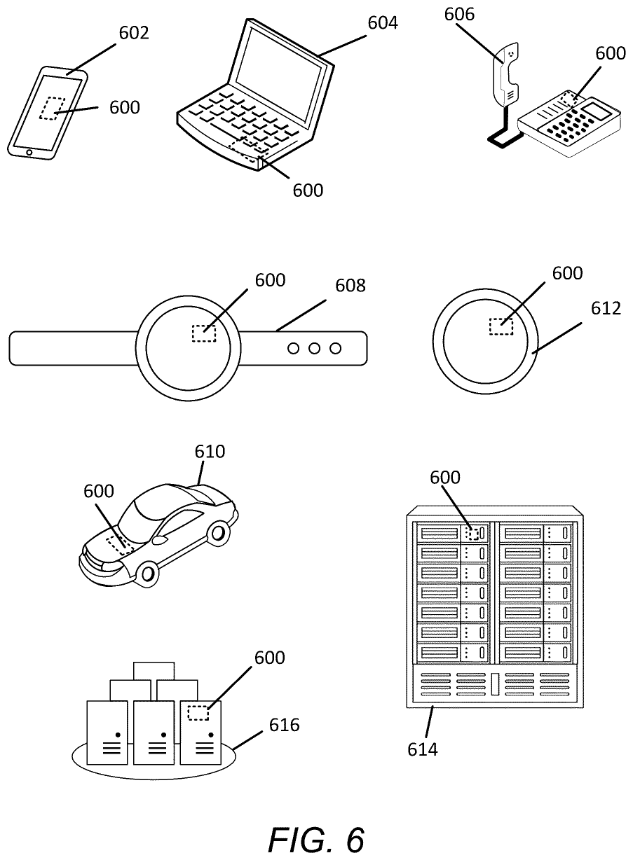

FIG. 6 illustrates various apparatuses (e.g., electronic devices) in which any of the semiconductor devices and/or electronic packages, such as the semiconductor packages disclosed herein, may be integrated, according to aspects of the disclosure. In an aspect, the semiconductor devices and/or electronic packages 600 may be integrated into user equipment (UE), including, by way of example and not limitation, a mobile phone device 602, a laptop computer device 604, a fixed-location terminal device 606, or a wearable device 608.

In other aspects, the semiconductor devices and/or electronic packages 600 may be integrated into electronic devices utilized in automotive applications. Such devices may include, by way of example and not limitation, sensors, controllers, processors, infotainment devices, and the like, which may be installed in a vehicle 610.

In yet other aspects, the semiconductor devices and/or electronic packages 600 may be integrated into a short-range device (SRD) 612. The SRD 612 may comprise, for example, one or more sensors, robotic machines, product code identifiers, electronic pricing and display labels, Internet of Things (IoT) devices, radio frequency identification (RFID) devices, Bluetooth Low Energy® (BLE) devices, or other similar devices.

In further aspects, the semiconductor devices and/or electronic packages 600 may be integrated into a server 614. The server 614 may comprise a computer system configured to provide services, data, or resources to other computers over a network. Such a server 614 may include one or more processors, integrated memory devices, power supplies, or other components mounted in one or more racks.

In yet other aspects, the semiconductor devices and/or electronic packages 600 may be integrated into a data center 616. The data center 616 may comprise a facility configured with one or more servers, storage devices, networking devices, and other supporting devices for storing, processing, and managing data.

The semiconductor devices and/or electronic packages 600 disclosed herein may be fabricated in various package configurations, including, but not limited to, side-by-side (SxS) packages, system-in-package (SiP) configurations, integrated circuit (IC) packages, package-on-package (PoP) devices, or any other suitable packaging configuration, whether disclosed herein or known in the art.

It will be appreciated, based on the teachings of the present disclosure, that the various apparatuses 602, 604, 606, 608, 610, 612, 614, and 616 illustrated in FIG. 6 are merely exemplary. Other apparatuses in which the semiconductor devices and/or electronic packages 600 may be integrated include, without limitation, mobile devices, hand-held personal communication system (PCS) units, portable data units (e.g., personal digital assistants), global positioning system (GPS)-enabled devices, navigation devices, set-top boxes, music players, video players, entertainment units, fixed-location data units, communication devices, smartphones, tablets, computers, wearable devices, servers, routers, memory devices, data centers, automotive electronic devices, Internet of Things (IoT) devices, or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A semiconductor package, comprising: a substrate with a first surface facing upward and a second surface facing downward; one or more vias within the substrate and extending from the first and second surfaces of the substrate, wherein upper surfaces of the one or more vias are planar with the first surface of the substrate and wherein lower surfaces of the one or more vias are planar with the second surface of the substrate; a first metal layer on the first surface of the substrate, the first metal layer comprising one or more first connection pads, one or more first traces, and one or more first via pads, wherein the upper surfaces of the one or more vias are electrically coupled with the one or more first via pads; a second metal layer on the second surface of the substrate, the second metal layer comprising one or more second connection pads, one or more second traces, and one or more second via pads, wherein the lower surfaces of the one or more vias are electrically coupled with the one or more second via pads; and one or more plated metals within the substrate below the first surface of the substrate, wherein an upper surface of at least one plated metal is in contact with a lower surface of at least one first connection pad or a lower surface of at least one first trace.

Clause 2: The semiconductor package of clause 1, wherein a side surface of the at least one first connection pad is in contact with a side surface of the at least one first trace, and wherein the upper surface of the at least one plated metal is in contact with the lower surfaces of the at least one first connection pad and the at least one first trace.

Clause 3: The semiconductor package of any of clauses 1-2, wherein the one or more first connection pads includes one or more IOP pads, or one or more peripheral bump pads, or both.

Clause 4: The semiconductor package of any of clauses 1-3, wherein the at least one first trace is a trace from a peripheral bump pad.

Clause 5: The semiconductor package of any of clauses 1-4, wherein a thickness of the one or more plated metals is 10 μm or less.

Clause 6: The semiconductor package of any of clauses 1-5, wherein the one or more plated metals are formed from copper (Cu).

Clause 7: The semiconductor package of any of clauses 1-6, wherein any one or more of the one or more first connection pads, the one or more first traces, and the one or more first via pads are formed from copper (Cu).

Clause 8: The semiconductor package of any of clauses 1-7, wherein a width of the one or more first traces is 5 μm or less.

Clause 9: The semiconductor package of any of clauses 1-8, wherein a spacing between adjacent first traces is 7 μm or less.

Clause 10: The semiconductor package of any of clauses 1-9, further comprising: a first solder resist (SR) on the substrate and on the first metal layer from above, wherein there are one or more first SR openings exposing the first metal layer, and wherein for at least one first SR opening, a plated metal of the one or more plated metals is in between the substrate and the first metal layer at a location corresponding to the at least one first SR opening, an upper surface of the plated metal being in contact with a lower surface of the first metal layer.

Clause 11: The semiconductor package of any of clauses 1-10, further comprising: one or more second plated metals on the second metal layer from below, wherein an upper surface of at least one second plated metal is in contact with a lower surface of at least one second connection pad or a lower surface of at least one second trace.

Clause 12: The semiconductor package clause 11, further comprising: a second solder resist (SR) on the substrate and on the second metal layer from below, wherein there are one or more second SR openings exposing the second metal layer, and wherein for at least one second SR opening, a second plated metal of the one or more second plated metals is at a location corresponding to the at least one second SR opening, an upper surface of the second plated metal being in contact with a lower surface of the second metal layer.

Clause 13: The semiconductor package of any of clauses 1-12, wherein the substrate is formed from any one or more of a dielectric, a laminate, a prepreg (PPG), a coreless substrate, and an embedded trace substrate (ETS).

Clause 14: The semiconductor package of any of clauses 1-13, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.

Clause 15: A method of fabricating a semiconductor package, the method comprising: providing a substrate with a first surface facing upward and a second surface facing downward; forming one or more vias within the substrate and extending from the first and second surfaces of the substrate, wherein upper surfaces of the one or more vias are planar with the first surface of the substrate and wherein lower surfaces of the one or more vias are planar with the second surface of the substrate; forming a first metal layer on the first surface of the substrate, the first metal layer comprising one or more first connection pads, one or more first traces, and one or more first via pads, wherein the upper surfaces of the one or more vias are electrically coupled with the one or more first via pads; forming a second metal layer on the second surface of the substrate, the second metal layer comprising one or more second connection pads, one or more second traces, and one or more second via pads, wherein the lower surfaces of the one or more vias are electrically coupled with the one or more second via pads; and forming one or more plated metals within the substrate below the first surface of the substrate, wherein an upper surface of at least one plated metal is in contact with a lower surface of at least one first connection pad or a lower surface of at least one first trace.

Clause 16: The method of clause 15, wherein a side surface of the at least one first connection pad is in contact with a side surface of the at least one first trace, and wherein the upper surface of the at least one plated metal is in contact with the lower surfaces of the at least one first connection pad and the at least one first trace.

Clause 17: The method of any of clauses 15-16, wherein the one or more first connection pads includes one or more IOP pads, or one or more peripheral bump pads, or both.

Clause 18: The method of any of clauses 15-17, wherein the at least one first trace is a trace from a peripheral bump pad.

Clause 19: The method of any of clauses 15-18, wherein a thickness of the one or more plated metals is 10 μm or less.

Clause 20: The method of any of clauses 15-19, wherein the one or more plated metals are formed from copper (Cu).

Clause 21: The method of any of clauses 15-20, wherein any one or more of the one or more first connection pads, the one or more first traces, and the one or more first via pads are formed from copper (Cu).

Clause 22: The method of any of clauses 15-21, wherein a width of the one or more first traces is 5 μm or less.

Clause 23: The method of any of clauses 15-22, wherein a spacing between adjacent first traces is 7 μm or less.

Clause 24: The method of any of clauses 15-23, further comprising: forming a first solder resist (SR) on the substrate and on the first metal layer from above, wherein there are one or more first SR openings exposing the first metal layer, and wherein for at least one first SR opening, a plated metal of the one or more plated metals is in between the substrate and the first metal layer at a location corresponding to the at least one first SR opening, an upper surface of the plated metal being in contact with a lower surface of the first metal layer.

Clause 25: The method of any of clauses 15-24, further comprising: forming one or more second plated metals on the second metal layer from below, wherein an upper surface of at least one second plated metal is in contact with a lower surface of at least one second connection pad or a lower surface of at least one second trace.

Clause 26: The method of clause 25, further comprising: forming a second solder resist (SR) on the substrate and on the second metal layer from below, wherein there are one or more second SR openings exposing the second metal layer, and wherein for at least one second SR opening, a second plated metal of the one or more second plated metals is at a location corresponding to the at least one second SR opening, an upper surface of the second plated metal being in contact with a lower surface of the second metal layer.

Clause 27: The method of any of clauses 15-26, wherein the substrate is formed from any one or more of a dielectric, a laminate, a prepreg (PPG), a coreless substrate, and an embedded trace substrate (ETS).

Clause 28: The method of any of clauses 15-27, wherein forming the one or more plated metals comprises: applying a mask on the first metal layer, wherein the first metal layer is on a carrier; patterning the mask to form one or more pattern holes to expose lower surfaces of the one or more first connection pads or lower surfaces of the one or more first traces or both; depositing a metal in the one or more pattern holes to form the one or more plated metals; removing the mask from the first metal layer; and forming the substrate on the first metal layer.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor package, comprising:
a substrate with a first surface facing upward and a second surface facing downward;
one or more vias within the substrate and extending from the first and second surfaces of the substrate, wherein upper surfaces of the one or more vias are planar with the first surface of the substrate and wherein lower surfaces of the one or more vias are planar with the second surface of the substrate;
a first metal layer on the first surface of the substrate, the first metal layer comprising one or more first connection pads, one or more first traces, and one or more first via pads, wherein the upper surfaces of the one or more vias are electrically coupled with the one or more first via pads;
a second metal layer on the second surface of the substrate, the second metal layer comprising one or more second connection pads, one or more second traces, and one or more second via pads, wherein the lower surfaces of the one or more vias are electrically coupled with the one or more second via pads; and
one or more plated metals within the substrate below the first surface of the substrate, wherein an upper surface of at least one plated metal is in contact with a lower surface of at least one first connection pad or a lower surface of at least one first trace.

2. The semiconductor package of claim 1,
wherein a side surface of the at least one first connection pad is in contact with a side surface of the at least one first trace, and
wherein the upper surface of the at least one plated metal is in contact with the lower surfaces of the at least one first connection pad and the at least one first trace.

3. The semiconductor package of claim 1, wherein the one or more first connection pads includes one or more IOP pads, or one or more peripheral bump pads, or both.

4. The semiconductor package of claim 1, wherein the at least one first trace is a trace from a peripheral bump pad.

5. The semiconductor package of claim 1, wherein a thickness of the one or more plated metals is 10 μm or less.

6. The semiconductor package of claim 1, wherein the one or more plated metals are formed from copper (Cu).

7. The semiconductor package of claim 1, wherein any one or more of the one or more first connection pads, the one or more first traces, and the one or more first via pads are formed from copper (Cu).

8. The semiconductor package of claim 1, wherein a width of the one or more first traces is 5 μm or less.

9. The semiconductor package of claim 1, wherein a spacing between adjacent first traces is 7 μm or less.

10. The semiconductor package of claim 1, further comprising:
a first solder resist (SR) on the substrate and on the first metal layer from above,
wherein there are one or more first SR openings exposing the first metal layer, and
wherein for at least one first SR opening, a plated metal of the one or more plated metals is in between the substrate and the first metal layer at a location corresponding to the at least one first SR opening, an upper surface of the plated metal being in contact with a lower surface of the first metal layer.

11. The semiconductor package of claim 1, further comprising:
one or more second plated metals on the second metal layer from below, wherein an upper surface of at least one second plated metal is in contact with a lower surface of at least one second connection pad or a lower surface of at least one second trace.

12. The semiconductor package of claim 11, further comprising:
a second solder resist (SR) on the substrate and on the second metal layer from below,
wherein there are one or more second SR openings exposing the second metal layer, and
wherein for at least one second SR opening, a second plated metal of the one or more second plated metals is at a location corresponding to the at least one second SR opening, an upper surface of the second plated metal being in contact with a lower surface of the second metal layer.

13. The semiconductor package of claim 1, wherein the substrate is formed from any one or more of a dielectric, a laminate, a prepreg (PPG), a coreless substrate, and an embedded trace substrate (ETS).

14. The semiconductor package of claim 1, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.

15. A method of fabricating a semiconductor package, the method comprising:
providing a substrate with a first surface facing upward and a second surface facing downward;
forming one or more vias within the substrate and extending from the first and second surfaces of the substrate, wherein upper surfaces of the one or more vias are planar with the first surface of the substrate and wherein lower surfaces of the one or more vias are planar with the second surface of the substrate;
forming a first metal layer on the first surface of the substrate, the first metal layer comprising one or more first connection pads, one or more first traces, and one or more first via pads, wherein the upper surfaces of the one or more vias are electrically coupled with the one or more first via pads;
forming a second metal layer on the second surface of the substrate, the second metal layer comprising one or more second connection pads, one or more second traces, and one or more second via pads, wherein the lower surfaces of the one or more vias are electrically coupled with the one or more second via pads; and
forming one or more plated metals within the substrate below the first surface of the substrate, wherein an upper surface of at least one plated metal is in contact with a lower surface of at least one first connection pad or a lower surface of at least one first trace.

16. The method of claim 15,
wherein a side surface of the at least one first connection pad is in contact with a side surface of the at least one first trace, and
wherein the upper surface of the at least one plated metal is in contact with the lower surfaces of the at least one first connection pad and the at least one first trace.

17. The method of claim 15, further comprising:
forming a first solder resist (SR) on the substrate and on the first metal layer from above,
wherein there are one or more first SR openings exposing the first metal layer, and
wherein for at least one first SR opening, a plated metal of the one or more plated metals is in between the substrate and the first metal layer at a location corresponding to the at least one first SR opening, an upper surface of the plated metal being in contact with a lower surface of the first metal layer.

18. The method of claim 15, further comprising:
forming one or more second plated metals on the second metal layer from below, wherein an upper surface of at least one second plated metal is in contact with a lower surface of at least one second connection pad or a lower surface of at least one second trace.

19. The method of claim 18, further comprising:
forming a second solder resist (SR) on the substrate and on the second metal layer from below,
wherein there are one or more second SR openings exposing the second metal layer, and
wherein for at least one second SR opening, a second plated metal of the one or more second plated metals is at a location corresponding to the at least one second SR opening, an upper surface of the second plated metal being in contact with a lower surface of the second metal layer.

20. The method of claim 15, wherein forming the one or more plated metals comprises:
applying a mask on the first metal layer, wherein the first metal layer is on a carrier;
patterning the mask to form one or more pattern holes to expose lower surfaces of the one or more first connection pads or lower surfaces of the one or more first traces or both;
depositing a metal in the one or more pattern holes to form the one or more plated metals;
removing the mask from the first metal layer; and
forming the substrate on the first metal layer.
